(19) United States
(12) Patent Application Publication
(10) Pub. No.: US 2026/0136459 A1
(43) Pub. Date: May 14, 2026

(54) PRINTED CIRCUIT BOARD

(71) Applicant: SAMSUNG ELECTRO-MECHANICS CO., LTD., Suwon-si (KR)

(72) Inventor: Byung Hak KANG, Suwon-si (KR)

(73) Assignee: SAMSUNG ELECTRO-MECHANICS CO., LTD., Suwon-si (KR)

(21) Appl. No.: 19/326,115

(22) Filed: Sep. 11, 2025

(30) Foreign Application Priority Data
Nov. 8, 2024 (KR) 10-2024-0157998

(51) Int. Cl. H05K 1/02; H05K 1/11; H05K 1/18

(52) U.S. Cl. CPC H05K 1/0298; H05K 1/115; H05K 1/182; H05K 2201/09827; H05K 2201/10015

(57) ABSTRACT

A printed circuit board includes a first wiring portion having a first insulating body and multiple first wiring layers. The first wiring portion is embedded in an upper side of the first insulating body, and at least part of an upper surface of the uppermost first wiring layer is exposed from the insulating body. A second wiring portion is disposed below the first wiring portion and includes a second insulating body and multiple second wiring layers. An electronic component is embedded in the first insulating body and partially exposed. The first wiring portion has a higher wiring density than the second wiring portion.

### CROSS-REFERENCE TO RELATED APPLICATION(S)

This application claims the benefit of priority to Korean Patent Application No. 10-2024-0157998 filed on Nov. 8, 2024 with the Korean Intellectual Property Office, the disclosure of which is incorporated herein by reference in its entirety.

### TECHNICAL FIELD

The present disclosure relates to a printed circuit board.

Due to implementation of high performance of semiconductor chips such as APs of smartphones, CPUs for servers, and AI accelerators, demand for package substrates including high-density circuits has been growing. Accordingly, bump pitch has been shrinking, and high layer counts and large substrate areas have been increasingly required. In addition, in order to respond to the growing number of input and output terminals, microcircuit implementation technology has become increasingly important.

### SUMMARY

An aspect of the present disclosure is to provide a printed circuit board capable of facilitating formation of a microcircuit and reducing the number of layers to reduce an overall package thickness, the printed circuit board having excellent power characteristics and/or die-to-die micro-connections.

A first wiring portion including a microcircuit may be formed on a carrier, a coreless-type second wiring portion may be formed on the first wiring portion, and an electronic component may be embedded in a first layer of the first wiring portion.

According to an aspect of the present disclosure, there is provided a printed circuit board including a first wiring portion including a first insulating body and a plurality of first wiring layers respectively disposed in the first insulating body, the first wiring portion in which an uppermost first wiring layer, among the plurality of first wiring layers, is embedded in an upper side of the first insulating body, the first wiring portion in which at least a portion of an upper surface of the uppermost first wiring layer is exposed from an upper surface of the first insulating body, a second wiring portion disposed on a lower side of the first wiring portion, the second wiring portion including a second insulating body and a plurality of second wiring layers respectively disposed in the second insulating body, and an electronic component embedded in the upper side of the first insulating body such that at least a portion of an upper surface thereof is exposed from the upper surface of the first insulating body. The plurality of first and second wiring layers may be electrically connected to each other. A minimum pitch of a wiring, included in each of the plurality of first wiring layers, may be less than a minimum pitch of a wiring, included in each of the plurality of second wiring layers.

According to another aspect of the present disclosure, there is provided a printed circuit board including a first wiring portion including a first insulating body and a plurality of first wiring layers respectively disposed in the first insulating body, the first wiring portion in which an uppermost first wiring layer, among the plurality of first wiring layers, is embedded in an upper side of the first insulating body, the first wiring portion in which at least a portion of an upper surface of the uppermost first wiring layer is exposed from an upper surface of the first insulating body, a second wiring portion disposed on a lower side of the first wiring portion, the second wiring portion including a second insulating body and a plurality of second wiring layers respectively disposed in the second insulating body, and an electronic component embedded in the upper side of the first insulating body such that at least a portion of an upper surface thereof is exposed from the upper surface of the first insulating body. The plurality of first and second wiring layers may be electrically connected to each other. A minimum insulation distance between the plurality of first wiring layers may be less than a minimum insulation distance between the plurality of second wiring layers.

According to example embodiments of the present disclosure, a printed circuit board may facilitate formation of a microcircuit and reduce the number of layers to reduce an overall package thickness, and may have excellent power characteristics and/or die-to-die micro-connections.

### BRIEF DESCRIPTION OF DRAWINGS

The above and other aspects, features, and advantages of the present disclosure will become more clearly understood from the following detailed description, taken in conjunction with the accompanying drawings, in which:

FIG. 1 is a schematic block diagram of an example of an electronic device system;

FIG. 2 is a schematic cross-sectional view of an example of a printed circuit board; and

FIG. 3 is a schematic cross-sectional view of another example of a printed circuit board.

### DETAILED DESCRIPTION

Hereinafter, example embodiments of the present disclosure are described with reference to the accompanying drawings. The shapes and sizes of components in the drawings may be exaggerated or reduced for clearer description.

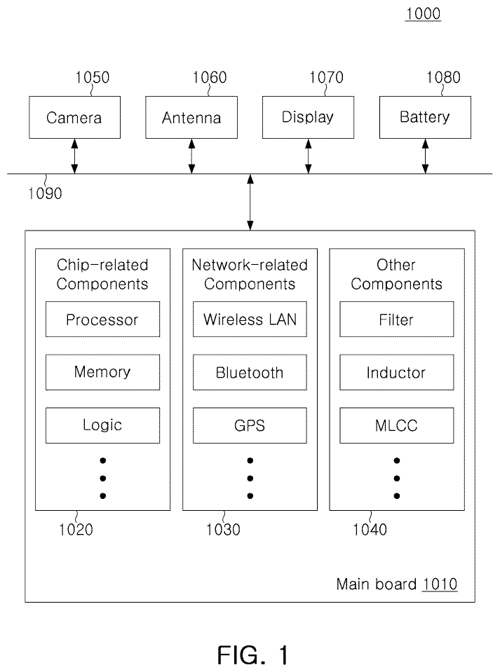

FIG. 1 is a schematic block diagram of an example of an electronic device system.

Referring to the drawings, an electronic device 1000 may accommodate a mainboard 1010. The mainboard 1010 may include chip-related components 1020, network-related components 1030, and other components 1040, physically or electrically connected thereto. These components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are not limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

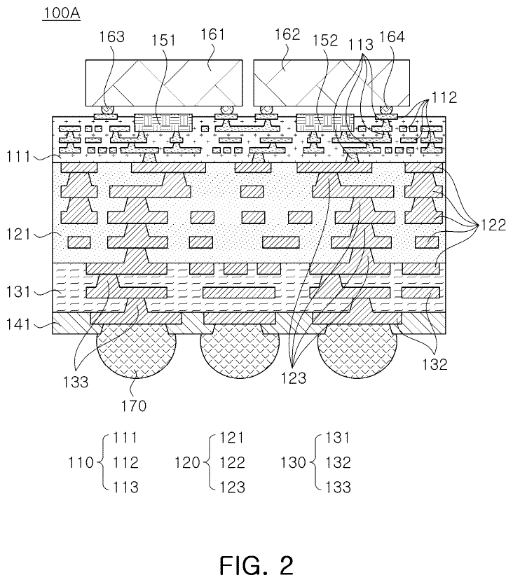

FIG. 2 is a schematic perspective view of an example of an electronic device.

Referring to the drawings, a printed circuit board 100A according to an example may include a first wiring portion 110 including a first insulating body 111 and a plurality of first wiring layers 112 respectively disposed in the first insulating body 111, the first wiring portion 110 in which an uppermost first wiring layer 112, among the plurality of first wiring layers 112, is embedded in an upper side of the first insulating body 111, the first wiring portion 110 in which at least a portion of an upper surface of the uppermost first wiring layer 112 is exposed from an upper surface of the first insulating body 111, a second wiring portion 120 disposed on a lower side of the first wiring portion 110, the second wiring portion 120 including a second insulating body 121 and a plurality of second wiring layers 122 respectively disposed in the second insulating body 121, and an electronic component embedded in the upper side of the first insulating body 111 such that at least a portion of an upper surface thereof is exposed from the upper surface of the first insulating body 111, for example, a plurality of chip capacitors 151 and 152. A plurality of first and second wiring layers 112 and 122 may be electrically connected to each other. The plurality of chip capacitors 151 and 152 may be electrically connected to the plurality of first wiring layers 112.

In this case, the first wiring portion 110 may include a wiring region having a density relatively higher than that of the second wiring portion 120. For example, a minimum pitch of a wiring, included in each of the plurality of first wiring layers 112, may be less than a minimum pitch of a wiring, included in each of the plurality of second wiring layers 122. In addition, a line width and the minimum pitch of the wiring, included in each of the plurality of first wiring layers 112, may be less than a line width and the minimum pitch of the wiring, included in each of the plurality of second wiring layers 122. In addition, a minimum insulation distance between the plurality of first wiring layers 112 may be less than a minimum insulation distance between the plurality of second wiring layers 122. In addition, a thickness of each of the plurality of first wiring layers 112 may be less than a thickness of each of the plurality of second wiring layers 122. In addition, an overall thickness of the first insulating body 111 may be less than an overall thickness of the second insulating body 121.

As described, in the printed circuit board 100A according to an example, the first wiring portion 110 including a relatively high-density wiring region may have an embedded trace substrate (ETS) structure. For example, the first wiring portion 110 may be formed on a carrier having excellent flatness, such as glass, silicon, or metal, using an ETS method. Thus, in the printed circuit board 100A according to an example, a microcircuit may be more easily formed. In this case, when an M1 layer having the ETS structure is formed, the electronic component, for example, the plurality of chip capacitors 151 and 152, may be disposed and embedded, and thus, the chip capacitors 151 and 152 may be disposed on an outermost side of the first wiring portion 110 to minimize a distance from a die mounted on a substrate, thereby improving power characteristics. In addition, the second wiring portion 120 may be formed on the first wiring portion 110 using a coreless method. Thus, the number of layers may be reduced, thereby reducing an overall package thickness and easily responding to high layer counts and large substrate areas. As a result, die-to-die connections may be achieved at a substrate level without the use of a 2.5D or 2.3D interposer or other similar technologies, thereby reducing process difficulty and cost, and lowering the difficulty of embedding the electronic component.

The wiring, included in each of the plurality of first wiring layers 112, may have a minimum line width greater than 0 μm and less than or equal to 2 μm, and a minimum distance between the wirings may be greater than 0 μm and less than or equal to 2 μm. In addition, the wiring included in each of a plurality of second wiring layers 122 may have a minimum line width greater than 2 μm and less than or equal to 5 μm, and a minimum distance between the wirings may be greater than 2 μm and less than or equal to 5 μm. In this case, the printed circuit board 100A according to an example may more easily replace a role of an interposer according to the related art.

The first wiring portion 110 may further include a plurality of first via layers 113 respectively disposed in the first insulating body 111, the plurality of first via layers 113 respectively connected to at least one first wiring layer 112, among the plurality of first wiring layers 112. In addition, the second wiring portion 120 may further include a plurality of second via layers 123 respectively disposed in the second insulating body 121, the plurality of second via layers 123 respectively connected to at least one second wiring layer 122, among the plurality of second wiring layers 122. In this case, a connection via, included in each of the plurality of first and second via layers 113 and 123, may have a substantially tapered side surface in the same direction, in cross-section. For example, the connection via, included in each of the plurality of first and second via layers 113 and 123, may have a substantially tapered side surface having an upper end having a width, less than a width of a lower end thereof, in cross-section. As described above, the first wiring portion 110 may be formed on the carrier using the ETS method, and the second wiring portion 120 may be formed on the first wiring portion 110 using the coreless method, and thus the plurality of first and second via layers 113 and 123 may have such a tapered structure.

In the first wiring portion 110, the upper surface of the uppermost first wiring layer 112 may protrude onto the upper surface of the first insulating body 111, such that a portion of a side surface of the uppermost first wiring layer 112 may protrude from the first insulating body 111. For example, after the carrier is detached, a portion of the upper side of the first insulating body 111 may be removed using plasma treatment such that the side surface of the uppermost first wiring layer 112, the M1 layer, is exposed. In this case, a portion of the uppermost first wiring layer 112 may protrude, and connection with a die may be facilitated. In this case, the electronic component, for example, an upper surface of each of the plurality of chip capacitors 151 and 152 may also protrude onto the upper surface of the first insulating body 111. As a result, the electronic component, for example, a portion of a side surface of each of a plurality of chip capacitors 151 and 152, may be exposed from the first insulating body 111.

Referring to the drawings, the printed circuit board 100A according to an example may further include a third wiring portion 130 disposed on a lower side of the second wiring portion 120, a third insulating body 131, one or more third wiring layers 132 disposed on or in the third insulating body 131, and one or more third via layers 133 respectively disposed in the third insulating body 131, the one or more third via layers 133 respectively connected to at least one third wiring layer 132 of the one or more third wiring layers 132. The plurality of second wiring layers 122 and the one or more third wiring layers 132 may be electrically connected to each other. The third wiring portion 130 may be formed on the second wiring portion 120 using the coreless method. The first wiring portion 110 may include a wiring region having a density relatively higher than that of the third wiring portion 120. In addition, a connection via, included in the third via layer 133, may have a substantially tapered side surface in a direction the same as that of a connection via, included in each of the plurality of first and second via layers 113 and 123.

The third insulating body 131 may include an insulating material, different from an insulating material included in at least one of the first and second insulating bodies 111 and 121. For example, the third insulating body 131 may include an insulating material having an elastic modulus, greater than that of an insulating material included in at least one of the first and second insulating bodies 111 and 121. For example, the third insulating body 131 may include an insulating material further including a glass fiber in addition to an insulating resin and an inorganic filler, for example, a prepreg. In this case, it may be more effective in controlling warpage.

Referring to the drawings, the printed circuit board 100A according to an example may further include first and second semiconductor chips 161 and 162 respectively disposed on an upper side of the first wiring portion 110, the first and second semiconductor chips 161 and 162 respectively connected to the uppermost first wiring layer 112 through first and second connection members 163 and 164, a passivation layer 141 disposed on a lower side of the third wiring layer 132, the passivation layer 141 having a plurality of openings exposing at least a portion of a lowermost third wiring layer 132, among the one or more third wiring layers 132, and/or a plurality of electrical connection metals 170 respectively disclosed on the plurality of openings, the plurality of electrical connection metals 170 respectively connected to at least a portion of the lowermost third wiring layer 132. For example, the printed circuit board 100A according to an example may be a semiconductor package substrate capable of micro-connection between the first and second semiconductor chips 161 and 162 or an interposer substrate, and may be mounted on a main board or other package substrates through the plurality of electrical connection metals 170.

Hereinafter, components of the printed circuit board 100A according to an example embodiment will be described in more detail with reference to the drawings.

Each of the first to third insulating bodies 111, 121, and 131 may include an organic insulating material. The organic insulating material may include a thermosetting resin such as an epoxy resin, a thermoplastic resin such as polyimide, or an inorganic filler and/or a glass fiber together with the above-described insulating resins. For example, the first and second insulating bodies 111 and 121 may include an insulating material including an insulating resin and an inorganic filler, for example, an ABF, but the present disclosure is not limited thereto. The first and second insulating bodies 111 and 121 may also include a photosensitive insulating material (PID) or the like. In addition, the third insulating body 131 may include an insulating material including an insulating resin, an inorganic filler, and a glass fiber, for example, a prepreg, but the present disclosure is not limited thereto. The first and second insulating bodies 111 and 121 may include substantially the same insulating material, but may also include different insulating materials. Each of the first to third insulating bodies 111, 121, and 131 may include one or more insulating layers or a plurality of insulating layers, and the insulating layers may be integrated with each other such that boundaries therebetween are readily apparent or are not readily apparent.

Each of the first to third wiring layers 112, 122, and 132 may include a metal. The metal may include copper (Cu), aluminum (Al), silver (Ag), tin (Sn), gold (Au), nickel (Ni), lead (Pb), titanium (Ti), and/or alloys thereof. For example, the first to third wiring layers 112, 122, and 132 may include chemical copper, formed using electroless plating, as a seed layer, and may include electrolytic copper, formed using electrolytic plating based thereon, as a pattern plating layer. However, the present disclosure is not limited thereto, and each of the first to third wiring layers 112, 122, and 132 may include a titanium (Ti) layer and a copper (Cu) layer, formed using sputtering, as a seed layer. Each of the first to third wiring layers 112, 122, and 132 may perform various functions depending on a design thereof. For example, each of the first to third wiring layers 112, 122, and 132 may include a signal transmission wiring, a power transmission wiring, a ground transmission wiring, and the like. The wirings may have various pattern shapes such as a line, a trace, a plane, a pad, and a land. Each of the first to third wiring layers 112, 122, and 132 may be one or more layers or a plurality of layers.

Each of the first to third via layers 113, 123, and 133 may include a metal. The metal may include copper (Cu), aluminum (Al), silver (Ag), tin (Sn), gold (Au), nickel (Ni), lead (Pb), titanium (Ti), and/or alloys thereof. For example, each of the first to third via layers 113, 123, and 133 may include chemical copper, formed using electroless plating, as a seed layer, and may include electrolytic copper, formed using electrolytic plating based thereon, as a pattern plating layer. However, the present disclosure is not limited thereto. Each of the first to third via layers 113, 123, and 133 may include a titanium (Ti) layer and a copper (Cu) layer, formed using sputtering, as a seed layer. Each of the first to third via layers 113, 123, and 133 may perform various functions depending on a design thereof. For example, each of the first to third via layers 113, 123, and 133 may include a signal transmission via, a power transmission via, a ground transmission via, and the like. A connection via, included in each of the first to third via layers 113, 123, and 133, may have a substantially tapered side surface having an upper end having a width, less than a width of a lower end thereof, in cross-section. The connection via, included in each of the first to third via layers 113, 123, and 133, may be provided as a plurality of connection vias. The connection via, included in each of the first to third via layers 113, 123, and 133, may have a fill-plated via structure, but the present disclosure is not limited thereto, and may have a conformally plated via structure.

The passivation layer 141 may include an organic insulating material. The organic insulating material may include a thermosetting resin such as an epoxy resin, a thermoplastic resin such as polyimide, or an inorganic filler and/or an organic filler together with the above-described resins. For example, the organic insulating material may be an ABF, a PID, a solder resist (SR), or the like, but the present disclosure is not limited thereto. The passivation layer 141 may have a plurality of openings respectively exposing at least a portion of the lowermost third wiring layer 132. At least a portion of the lowermost third wiring layer 132, respectively exposed through the plurality of openings, may be of a solder mask defined (SMD) and/or a non-solder mask defined (NSMD) type.

Each of the chip capacitors 151 and 152 may be a multilayer ceramic capacitor (MLCC), but the present disclosure is not limited thereto. The electronic component is not limited to the chip capacitors 151 and 152, and may include various other types of active components and/or passive components in addition to the chip capacitors 151 and 152. For example, the active component may include various types of semiconductor chips, and the passive component may include various types of chip-type components, such as a chip inductor and the like, in addition to the chip capacitor. The electronic component may be embedded in an uppermost side of the first wiring portion 110, as described above.

Each of the semiconductor chips 161 and 162 may include an integrated circuit (IC) die in which an integrated circuit (IC) die in which hundreds to millions of devices are integrated into a single chip. In this case, the IC may be, for example, a logic chip such as a central processing unit (for example, a CPU), a graphics processing unit (for example, a GPU), a field programmable gate array (FPGA), a digital signal processor, a cryptographic processor, a microprocessor, a microcontroller, an application processor (for example, an AP), an analog-to-digital converter, an application-specific IC (ASIC), or the like, but the present disclosure is not limited thereto, and may also be a memory chip such as a volatile memory (for example, DRAM), a non-volatile memory (for example, ROM), a flash memory, a high bandwidth memory (HBM), or the like, or a power management IC (PMIC).

Each of the connection members 163 and 164 and the electrical connection metal 170 may be formed of a low melting point metal, for example, solder such as tin (Sn)-aluminum (Al)-copper (Cu), or the like, but the material is only an example and is not limited thereto. Each of the connection members 163 and 164 may be a ball, a pin, or the like. Each of the plurality of first and second electrical connection metals 161 and 162 may be formed of multiple layers or a single layer. Each of the plurality of first and second electrical connection metals 161 and 162 may include a copper pillar and solder when formed of multiple layers, and may include tin-silver solder when formed of a single layer, but the present disclosure is not limited thereto. The connection members 163 and 164 and the electrical connection metal 170 may be provided as a plurality of connection members and a plurality of electrical connection metals, respectively.

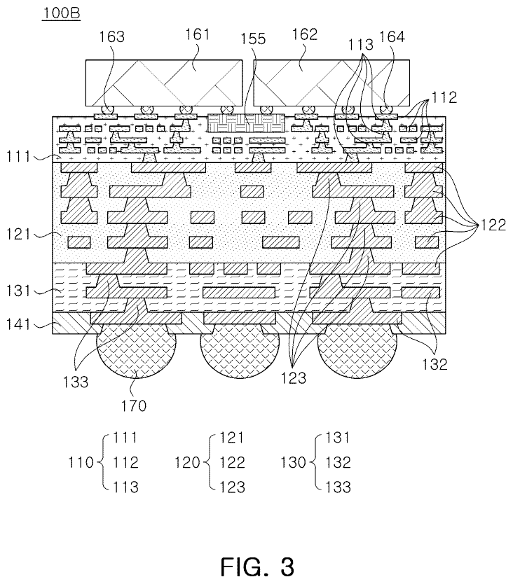

FIG. 3 is a schematic cross-sectional view of another example of a printed circuit board.

Referring to the drawings, as compared to the above-described printed circuit board 100A according to an example, in a printed circuit board 100B according to another example, an interconnect bridge 155 may be embedded as an electronic component in an uppermost side of a first wiring portion 110. The interconnect bridge 155 may be electrically connected to each of first and second semiconductor chips 161 and 162. The arrangement of the interconnect bridge 155 may enable a high-density die-to-die connection having a line(L)/space(S) of 2/2 um or less to be locally achieved. In particular, as described above, when the first wiring portion 110 is formed using an ETS method, the interconnect bridge 155 may be disposed and embedded when an M1 layer having an ETS structure is formed, thereby minimizing a distance between the embedded interconnect bridge 155 and the first and second semiconductor chips 161 and 162, mounted on the first wiring portion 110. Accordingly, signal loss or the like may be minimized, and signal characteristics may be improved. In addition, the difficulty of embedding may also be reduced. The interconnect bridge 155 may be a silicon-type bridge and/or an organic-type bridge, and may include a high-density circuit.

Other descriptions may be substantially the same as those described in connection with the above-described printed circuit board 100A according to an example. In addition, the technical effects described in connection with the printed circuit board 100A according to an example may also be applied to the printed circuit board 100B according to another example in substantially the same manner.

As used herein, the terms “cover,” “to cover,” and “covering” may include entirely covering as well as at least partially covering, and may include directly covering as well as indirectly covering. In addition, the terms “fill,” “to fill,” and “filling” may include not only entirely filling, but also approximately filling, for example, may include a case in which some voids, pores or the like are present. In addition, the terms “surround,” “to surround,” and “surrounding” may include not only entirely surrounding but also approximately surrounding. In addition, exposing may include not only entirely exposing but also exposing at least a portion of a structure, and exposure may mean exposing a component from another component in which the component is embedded. For example, an opening, exposing a pad, may be exposing the pad from a resist layer, and a surface treatment layer may be further disposed on the exposed pad.

As used herein, a process error or a positional deviation occurring in a manufacturing process, an error in measurement, and the like may be included. For example, “substantially coplanar” may include not only “completely coplanar,” but also “approximately coplanar.” In addition, “being disposed on substantially the same level” may include not only “being disposed on completely the same level,” but also “being disposed on approximately the same level.” In addition, “having a substantially specific shape” may include not only “having a completely specific shape,” but also “having an approximately specific shape.” In addition, the same insulating material may mean not only the exact same insulating material, but also the same type of insulating material. Thus, compositions of insulating materials may be substantially the same, but specific composition ratios thereof may slightly vary.

As used herein, “in cross-section” may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions, and the concepts of “upper” and “lower” may change at any time.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, a thickness, a width, a length, a depth, a line width, a space, a pitch, and the like may be measured using a scanning microscope or an optical microscope based on a cross-section obtained by polishing or cutting a printed circuit board. The cross-section may be a vertical cross-section or a horizontal cross-section, and each value may be measured based on the required cross-section. For example, a width of an upper end and/or lower end of a via may be measured in cross-section taken along a central axis of the via. In this case, when a component does not have a predetermined value, the value may be determined as an average value of values measured at arbitrary five points.

As used herein, the term “an example” does not mean the same example embodiment, and is provided to emphasize different unique features. However, the examples presented above do not preclude implementation in combination with features of other examples. For example, a context described in a specific example may be used in other examples, even if it is not described in the other example examples, unless it is described contrary to or inconsistent with the context in the other examples.

The terms used herein describe particular examples only, and the present disclosure is not limited thereto. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
a first wiring portion including a first insulating body and a plurality of first wiring layers respectively disposed in the first insulating body, the first wiring portion in which an uppermost first wiring layer, among the plurality of first wiring layers, is embedded in an upper side of the first insulating body, the first wiring portion in which at least a portion of an upper surface of the uppermost first wiring layer is exposed from an upper surface of the first insulating body;
a second wiring portion disposed on a lower side of the first wiring portion, the second wiring portion including a second insulating body and a plurality of second wiring layers respectively disposed in the second insulating body; and
an electronic component embedded in the upper side of the first insulating body such that at least a portion of an upper surface thereof is exposed from the upper surface of the first insulating body,
wherein the plurality of first and second wiring layers are electrically connected to each other, and
a minimum pitch of a wiring, included in each of the plurality of first wiring layers, is less than a minimum pitch of a wiring, included in each of the plurality of second wiring layers.

2. The printed circuit board of claim 1, wherein a minimum line width and a minimum distance between wirings in each of the plurality of first wiring layers are less than a minimum line width and a minimum distance between wirings in each of the plurality of second wiring layers, respectively.

3. The printed circuit board of claim 2, wherein
the wiring, included in each of the plurality of first wiring layers, has the minimum line width greater than 0 μm and less than or equal to 2 μm, and the minimum distance between the wirings is greater than 0 μm and less than or equal to 2 μm, and
the wiring, included in each of the plurality of second wiring layers, has the minimum line width greater than 2 μm and less than or equal to 5 μm, and the minimum distance between the wirings is greater than 2 μm and less than or equal to 5 μm.

4. The printed circuit board of claim 1, wherein
the first wiring portion further includes a plurality of first via layers respectively disposed in the first insulating body, the plurality of first via layers respectively connected to at least one first wiring layer, among the plurality of first wiring layers,
the second wiring portion further includes a plurality of second via layers respectively disposed in the second insulating body, the plurality of second via layers respectively connected to at least one second wiring layer, among the plurality of second wiring layers, and
a connection via, included in each of the plurality of first and second via layers, has a substantially tapered side surface in the same direction in cross-section.

5. The printed circuit board of claim 1, wherein
a connection via included in each of the plurality of first and second via layers has a substantially tapered side surface having an upper end having a width, less than a width of a lower end thereof, in cross-section.

6. The printed circuit board of claim 1, wherein the upper surface of the uppermost first wiring layer protrudes onto the upper surface of the first insulating body, such that a portion of a side surface of the uppermost first wiring layer is exposed from the first insulating body.

7. The printed circuit board of claim 6, wherein an upper surface of the electronic component protrudes onto the upper surface of the first insulating body, such that a portion of a side surface of the electronic component is exposed from the first insulating body.

8. The printed circuit board of claim 1, wherein the electronic component comprises at least one chip capacitor.

9. The printed circuit board of claim 1, wherein the electronic component comprises at least one interconnect bridge.

10. The printed circuit board of claim 1, further comprising:
a third wiring portion disposed on a lower side of the second wiring portion, the third wiring portion including a third insulating body and one or more third wiring layers respectively disposed on or in the third insulating body,
wherein the plurality of second wiring layers and the one or more third wiring layers are electrically connected to each other, and
the third insulating body includes an insulating material, different from an insulating material of at least one of the first insulating body and the second insulating body.

11. The printed circuit board of claim 10, wherein the third insulating body includes an insulating material having an elastic modulus, greater than that of an insulating material included in at least one of the first insulating body and the second insulating body.

12. The printed circuit board of claim 10, further comprising:
first and second semiconductor chips respectively disposed on an upper side of the first wiring portion, the first and second semiconductor chips respectively connected to the uppermost first wiring layer through first and second connection members;
a passivation layer disposed on a lower side of the third wiring portion, the passivation layer having a plurality of openings respectively exposing at least a portion of a lowermost third wiring layer, among the one or more third wiring layers; and
a plurality of electrical connection metals respectively disposed on the plurality of openings, the plurality of electrical connection metals respectively connected to at least a portion of the lowermost third wiring layer.

13. A printed circuit board comprising:
a first wiring portion including a first insulating body and a plurality of first wiring layers respectively disposed in the first insulating body, the first wiring portion in which an uppermost first wiring layer, among the plurality of first wiring layers, is embedded in an upper side of the first insulating body, the first wiring portion in which at least a portion of an upper surface of the uppermost first wiring layer is exposed from an upper surface of the first insulating body;
a second wiring portion disposed on a lower side of the first wiring portion, the second wiring portion including a second insulating body and a plurality of second wiring layers respectively disposed in the second insulating body; and
an electronic component embedded in the upper side of the first insulating body such that at least a portion of an upper surface thereof is exposed from the upper surface of the first insulating body,
wherein the plurality of first and second wiring layers are electrically connected to each other, and
a minimum insulation distance between the plurality of first wiring layers is less than a minimum insulation distance between the plurality of second wiring layers.

14. The printed circuit board of claim 13, wherein a thickness of each of the plurality of first wiring layers is less than a thickness of each of the plurality of second wiring layers.

15. The printed circuit board of claim 13, wherein an overall thickness of the first insulating body is less than an overall thickness of the second insulating body.

16. The printed circuit board of claim 13, the second wiring portion is disposed on the first wiring portion using a coreless method.
